(19) United States
(12) Patent Application Publication
(10) Pub. No.: US 2013/0068248 A1
(43) Pub. Date: Mar. 21, 2013

(54) SEMICONDUCTOR DEVICE CLEANING METHOD

(71) Applicants: Ming-Hsi Yeh, Hsinchun (TW); Kuo-Sheng Chuang, Hsinchu City (TW); Ying-Hsueh Chang Chien, New Taipei City (TW); Chi-Ming Yang, Hsian-San District (TW); Chin-Hsiang Lin, Hsin-chu (TW)

(72) Inventors: Ming-Hsi Yeh, Hsinchun (TW); Kuo-Sheng Chuang, Hsinchu City (TW); Ying-Hsueh Chang Chien, New Taipei City (TW); Chi-Ming Yang, Hsian-San District (TW); Chin-Hsiang Lin, Hsin-chu (TW)

(73) Assignee: Taiwan Semiconductor Manufacturing Company, Ltd., ("TSMC"), Hsin-Chu (TW)

(21) Appl. No.: 13/233,568

(22) Filed: Sep. 15, 2011

(51) Int. Cl. H01L 21/00; C23G 1/02; B08B 5/02; B08B 3/08

(52) U.S. Cl. 134/3

(57) ABSTRACT

The present disclosure provides a method including providing a chamber having a first inlet and a second inlet. A solution of a de-ionized (DI) water and an acid (e.g., a dilute acid) is provided to the chamber via the first inlet. A carrier gas (e.g., N₂) is provided to the chamber via the second inlet. The solution and the carrier gas are in the chamber and then from the chamber onto a single semiconductor wafer. In an embodiment, the solution includes a dilute HCl and DI water.

### BACKGROUND

Embodiments of this disclosure relate generally to semiconductor device fabrication, and more particularly to a method of cleaning a semiconductor wafer during the fabrication.

Recent trends in the progression of semiconductor device fabrication have included the introduction of materials other than the typical choice of silicon in forming the device. For example, III-V materials such as germanium (Ge), gallium arsenide (GaAs), InP, and InGaAs have been implemented in advanced technologies nodes. These materials have a benefit of increased hole or electron movement and work function tuning. Thus, the advanced materials allow for an increased performance when used, for example, in the channel region of a semiconductor device.

Introduction of new materials to the typical silicon-based fabrication processes is not without its challenges however. One issue in the compatibility of the new materials with the traditionally applied chemicals. For example, compatibility with typically used wet cleaning solutions must be ensured. Thus, what is desired are fabrication process(es) that provide compatibility with the materials employed in these and future technology nodes.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart illustrating an embodiment of a method of cleaning a semiconductor wafer according to one or more aspects of the present disclosure.

FIG. 2 is a cross-sectional view of an embodiment of a wafer cleaning apparatus used in one or more aspects of the method of FIG. 1.

FIG. 3 is a cross-sectional view of another embodiment of a wafer cleaning apparatus used in one or more aspects of the method of FIG. 1.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. The term chemical as used herein substances created by reaction as well as naturally occurring reactive and/or inert substances. For example, exemplary chemicals would include nitrogen (N₂), air, water (including de-ionized water), acids, bases, solutions, pure substances, and the like. As also used herein, a solution of chemicals may be homogeneous or substantially homogeneous, but may not necessarily be so.

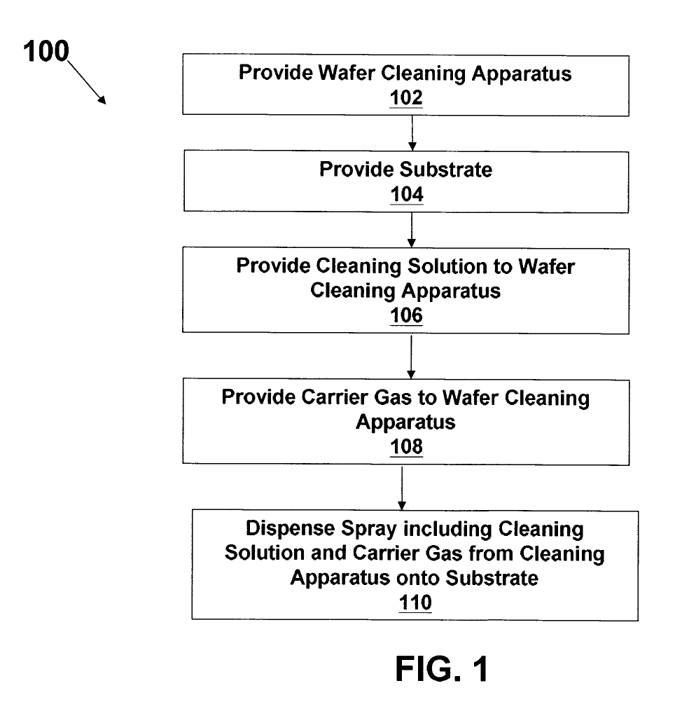

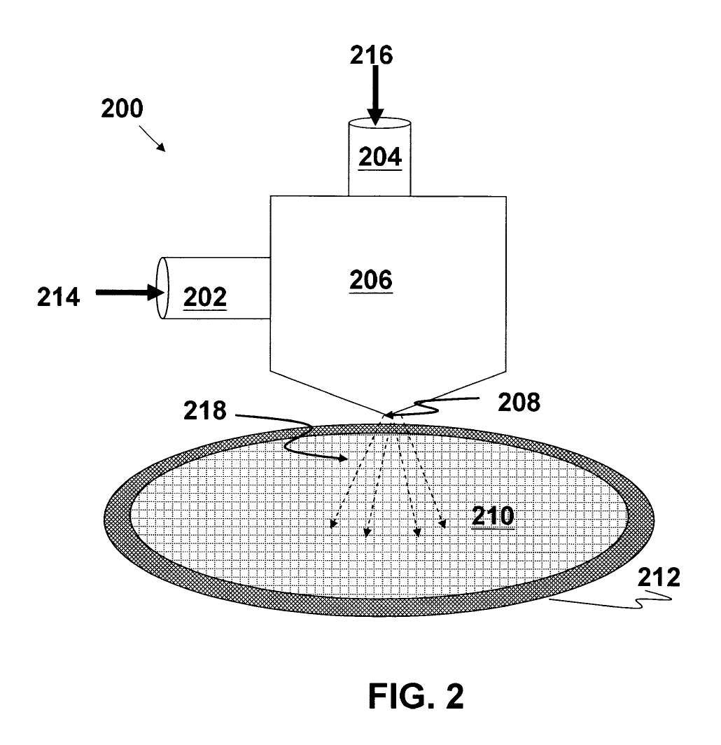

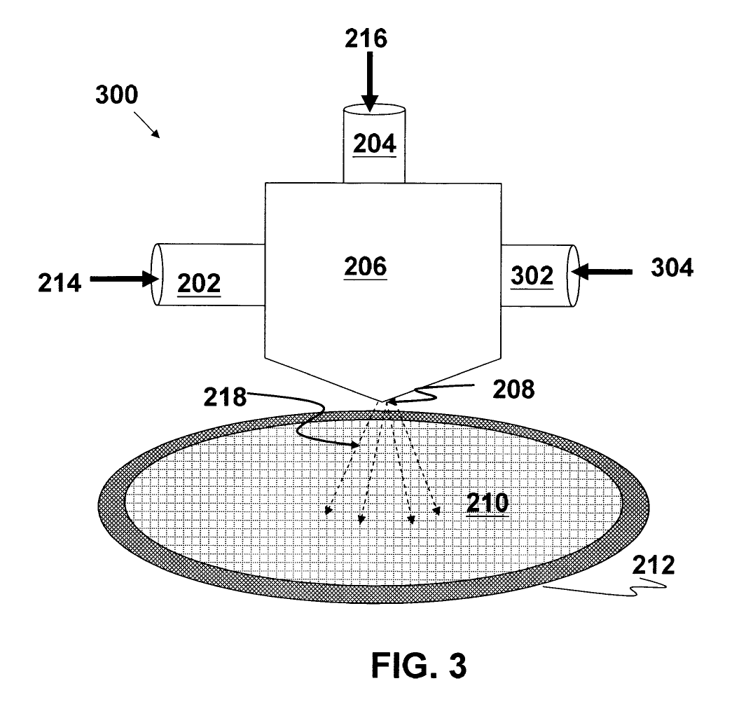

Illustrated in FIG. 1 is a flow chart of an embodiment of a method of cleaning a semiconductor substrate according to one or more aspects of the present disclosure. FIGS. 2-3 illustrate a cleaning apparatus which may be used to perform one or more steps of the method of FIG. 1.

The method 100 begins at block 102 where substrate (e.g., wafer) cleaning apparatus is provided. The apparatus may include inlets for receiving chemicals, a chamber within which one or more chemicals are mixed, a nozzle for dispensing the mixed chemicals, a wafer stage operable to hold and/or rotate a semiconductor substrate (e.g., wafer), and/or other suitable components. The apparatus may be a single wafer spray cleaning tool.

Referring now to the example of FIG. 2, illustrated is a wafer cleaning apparatus 200. The wafer cleaning apparatus 200 includes a first inlet 202 and a second inlet 204, which are connected to a chamber 206. The first and second inlet 202 and 204 may be connected to a chemical supply (e.g., de-ionized water, nitrogen, air, or other chemical solution). The chemical provided may be heated prior to, during or after the delivery to the inlets 202 and 204.

A wafer 210, described in further detail below, is disposed on a wafer stage 212. The wafer stage 212 is operable position the wafer 210 below the chamber 206 and specifically a nozzle 208. The wafer stage 212 may rotate the wafer 210 about an axis. The wafer cleaning apparatus 200 may also include a scan mode where the wafer 210 and/or the nozzle 208 are moved in a lateral motion such that a spray 218 from the nozzle 208 is incident different points on a diameter of the wafer 210. The wafer cleaning apparatus 200 may include any number of nozzles 208 in various configurations (e.g., a spray bar(s)). The wafer cleaning apparatus 200 is exemplary only and not intended to be limiting, the wafer cleaning apparatus may be provided in any suitable configuration including those typical of semiconductor fabrication equipment.

Referring now to the example of FIG. 3, illustrated is a wafer cleaning apparatus 300. The wafer cleaning apparatus 300 may be substantially similar to the wafer cleaning apparatus 200 except with differences mentioned herein. Specifically, the wafer cleaning apparatus 300 includes a first inlet 202, a second inlet 204, and an additional third inlet 302, all which are connected to a chamber 206. The first, second, and/or third inlet 202, 204, and 302 may be connected to a chemical supply (e.g., de-ionized water, nitrogen, air, or other chemical solution) and provide the same or different chemicals to the chamber 206.

The method 100 then proceeds to block 104 where a semiconductor substrate (e.g., wafer) is provided. The wafer may have a diameter of approximately 200 mm, approximately 300 mm, approximately 450 mm, or other suitable diameter. In embodiments, the wafer diameter may be larger than 450 mm.

The substrate may include any number of semiconductor devices or portion(s) thereof. In an embodiment, the substrate includes regions having Ge, GaAs, InP, InGaAs, and/or other suitable III-V semiconductor material(s). The III-V materials may be disposed on or in the substrate in regions where a channel of a semiconductor device (e.g., transistor) will be disposed. In an embodiment, the III-V semiconductor material is provided on a top surface of the semiconductor substrate. The top surface may be exposed to a spray from the wafer cleaning apparatus. For example, the III-V semiconductor material may be epitaxially grown on (and/or above) the substrate. In a further embodiment, the III-V semiconductor material may be deposited on the wafer using metalorganic vapor phase epitaxy (MOVPE) or metalorganic chemical vapor deposition (MOCVD) processes.

Referring to the example of FIGS. 2 and 3, a wafer 210 is illustrated. The wafer 210 may include silicon. In an embodiment, the substrate includes silicon and has regions having Ge, GaAs, InP, InGaAs, and/or other suitable III-V semiconductor material(s). Alternatively, the wafer 210 is germanium, silicon germanium or other proper semiconductor materials. The wafer 210 may include regions where one or more semiconductor devices, or portions thereof, are formed (e.g., field effect transistors). Various isolation features may be formed in the wafer 210 interposing various doped regions (e.g., n-wells and p-wells) formed in various active regions. The wafer 210 includes a plurality of individual die formed thereon, which may be subsequently diced to form semiconductor devices. In an embodiment, the wafer 210 is approximately 450 mm in diameter.

The method 100 then proceeds to block 106 where a cleaning solution is provided to the wafer cleaning apparatus. The cleaning solution includes an acid and de-ionized (DI) water. The cleaning solution may be a dilute acid. In an embodiment, the cleaning solution provided includes a dilute aqueous hydrochloric acid (HCl). In other embodiments, the cleaning solution includes acetic acid, citric acid, HCl and/or other suitable acids having a pH of less than approximately 7. The dilute acid may serve to reduce any metallic contamination on the wafer. The acid may be approximately 0.5 wt % acid or less (aqueous in DI water). In a further embodiment, the cleaning solution includes between approximately 0.3 wt % and approximately 0.0003 wt % of acid (e.g., HCl) in de-ionized (DI) water. The cleaning solution provided may be between approximately 4 Celsius and approximately 80 Celsius.

Referring to the example of FIGS. 2 and 3, a cleaning solution 216 is provided to the chamber 206 via the inlet 204. In an embodiment, the cleaning solution 216 is dilute acid. For example, HCl and DI water, acetic acid and DI water, citric acid and DI water, and/or other suitable acids having a pH of less than approximately 7 being diluted with DI water. The cleaning solution 216 may be between approximately 4 Celsius and approximately 80 Celsius.

The cleaning solution 216 may have a flow rate of between approximately 10 sccm and approximately 2000 sccm.

The method 100 then proceeds to block 108 were a carrier gas is provided to the wafer cleaning apparatus. The carrier gas may be nitrogen (N₂) gas. In other embodiments, the carrier gas is air, argon or other inert gas. The carrier gas may be provided at a high-pressure (e.g., greater than 760 torr.)

Referring to the example of FIGS. 2 and 3, a carrier gas 214 is provided to the chamber 206 via the inlet 202. In an embodiment, the carrier gas 214 is N₂. The carrier gas 214 may be provided at a flow rate of approximately 0.5 slm to approximately 500 slm.

The carrier gas may be provided to the wafer cleaning apparatus at one or more locations. In an embodiment, the carrier gas is injected into a chamber of a wafer cleaning apparatus at two or three sides of the chamber. For instance, FIG. 3 illustrates an inlet 302, opposing th3 inlet 202. A chemical 304 is provided to the chamber 206 via the inlet 302. In an embodiment, the chemical 304 is a carrier gas (e.g., N₂). In an embodiment, the chemical 304 is substantially similar to the carrier gas 214, described above.

The carrier gas may be suitable for removing particles and airborne molecular contamination (AMC) defects from the target wafer. The carrier gas may provide an atomic force spray or physical force onto the wafer, as described in further detail below.

The blocks 106 and 108 may occur simultaneously. The carrier gas and cleaning solution (e.g., dilute acid) may mix in the chamber (e.g., chamber 206).

The method 100 then proceeds to block 110 where a spray including the cleaning solution and the carrier gas, described above with reference blocks 106 and 108 respectively, is dispensed onto the semiconductor wafer. Referring to the example of FIGS. 2 and 3, a spray 218 is provided to the wafer 210. The spray 218 is provided by the nozzle 208. The spray 208 may be provided by any number of nozzles and in any configuration (e.g., spray bar(s)). Thus, the spray 218 may be incident one or more locations on the wafer 210. In an embodiment, the wafer cleaning apparatus includes a scan mode which moves the nozzle 208 and/or wafer 210 such that the spray 208 traverses a portion of the wafer 210. The wafer 210 may be rotated (e.g., by the wafer stage 212) while the spray 218 is incident the wafer 210 surface. In an embodiment, the wafer 210 may be rotated about its radial axis between approximately 10 rpm and approximately 2000 rpm during the dispensing.

The spray 218 includes the cleaning solution 216 and carrier gas 214, as illustrated in FIG. 2. (In other embodiments, the spray 218 may includes the cleaning solution 216, carrier gas 214, and chemical 304 (e.g., carrier gas) as illustrated in FIG. 3.) In an embodiment, the spray 218 includes a carrier gas in vapor form and diluted aqueous acid. For example, the spray 218 may include N₂ and dilute HCl(aq). The spray 218 may include a cleaning solution (e.g., dilute acid) at a flow rate of approximately 10 sccm to approximately 2000 sccm of cleaning solution. The spray 218 may include a flow rate of approximately 0.5 slm and approximately 500 slm of carrier gas. The temperature of the spray 218 may be between approximately 4 Celsius and approximately 80 Celsius.

In summary, the methods and devices disclosed herein provide for a cleaning method. The cleaning method may be applied to a substrate including a III-V material region (e.g., Ge, GaAs, InP, InGaAs). In doing so, the present disclosure offers, in some embodiments, advantages. For example, some methods disclosed herein provide a high cleaning efficiency due to the high-pressure carrier gas. The cleaning methods described herein may remove trace metallic contamination at the same time as the particle clean is performed (e.g., through the simultaneous dispersion of a solution including an acid. Further benefits of certain embodiments include less oxidation of the substrate including III-V region and/or a minimization of surface roughness. The device mobility and/or density of interface charging deficit (Dit) may be maintained.

Thus, the foregoing describes in an embodiment, a method of semiconductor device fabrication. The method includes providing a semiconductor wafer. A cleaning solution mixed with a carrier gas is then dispensed onto the semiconductor wafer. The cleaning solution is deionized water and an acid.

In a further embodiment, a channel region is formed on the semiconductor wafer by forming a region including at least one of Ge, GaAs, InP, and InGaA. The cleaning solution is dispensed onto the channel region.

The acid of the cleaning solution may be selected from the group of acids consisting of HCl, acetic acid and citric acid. An exemplary carrier gas is nitrogen. The carrier gas has may have a flow rate of between approximately 0.5 slm and approximately 500 slm.

In an embodiment, the method is performed by a wafer cleaning apparatus having a first inlet to a dispensing chamber, which provides the cleaning solution and a second inlet to the dispensing chamber, which provides the carrier gas. The cleaning solution and the carrier gas are the dispensing chamber. The cleaning solution mixed with the carrier gas is then dispensed onto the semiconductor wafer from the dispensing chamber. The method may be performed by a single wafer tool operable to clean a wafer having a diameter approximately 200 mm or greater.

In a further embodiment, the cleaning solution consists of de-ionized water and acid. The cleaning solution may include a dilute acid such as a weight percent between approximately 0.3 wt % and 0.0003 wt %.

In another embodiment of a method described in the present disclosure a dispensing chamber having a first inlet and a second inlet is provided. A solution of a de-ionized (DI) water and an acid are provided to the dispensing chamber via the first inlet and a carrier gas to the dispensing chamber via a second inlet. The solution and the carrier gas are mixed in the dispensing chamber. The solution mixed with the carrier gas is then dispensed from the dispensing chamber onto a single semiconductor wafer.

In still another embodiment, a method including dispensing a solution mixed with an inert, high-pressure carrier gas flow onto a single semiconductor substrate is described. The solution is an acid aqueous solution including less than 0.5 wt % acid.

The foregoing has outlined features of several embodiments. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of semiconductor device fabrication, comprising:
providing a semiconductor wafer;
dispensing a cleaning solution mixed with a carrier gas onto the semiconductor wafer, wherein the cleaning solution is de-ionized water and an acid.

2. The method of claim 1, further comprising:
forming a channel region on the semiconductor wafer, wherein the forming the channel region includes forming a region including at least one of Ge, GaAs, InP, InGaAs; and
wherein the cleaning solution is dispensed onto the channel region.

3. The method of claim 1, wherein the acid is selected from the group consisting of HCl, acetic acid and citric acid.

4. The method of claim 1, wherein the carrier gas is nitrogen.

5. The method of claim 3, wherein the carrier gas has a flow rate of between approximately 0.5 slm and approximately 500 slm.

6. The method of claim 1, further comprising:
providing a first inlet to a dispensing chamber carrying the cleaning solution;
providing a second inlet to a chamber carrying the carrier gas;
mixing the solution and the carrier gas in the chamber; and
wherein the dispensing the solution includes dispensing the solution mixed with the carrier gas onto the semiconductor wafer from the chamber.

7. The method of claim 1, wherein the semiconductor wafer diameter is approximately 200 mm or greater.

8. The method of claim 1, wherein the cleaning solution is between approximately 4 Celsius and approximately 80 Celsius.

9. The method of claim 1, wherein the cleaning solution of de-ionized water and acid includes between approximately 0.3 wt % and approximately 0.0003 wt % of acid.

10. The method of claim 9, wherein the cleaning solution consists of de-ionized water and the acid.

11. A method, comprising:
providing a chamber having a first inlet and a second inlet;
providing a solution of a de-ionized (DI) water and an acid to the chamber via the first inlet;
providing a carrier gas to the chamber via the second inlet;
mixing the solution and the carrier gas in the chamber; and
dispensing the solution mixed with the carrier gas from the chamber onto a single semiconductor wafer.

12. The method of claim 11, further comprising:
providing the carrier gas to the chamber via a third inlet to the chamber.

13. The method of claim 12, wherein the third inlet is on an opposing side of the chamber as the second inlet.

14. The method of claim 11, further comprising:
disposing the single semiconductor wafer on a stage; and
rotating the single semiconductor wafer between approximately 10 rpm and approximately 2000 rpm during the dispensing.

15. A method, comprising:
dispensing a solution mixed with an inert, high-pressure carrier gas flow onto a single semiconductor substrate, wherein the solution is an acid aqueous solution.

16. The method of claim 15, wherein the high-pressure gas flow is provided at greater than approximately 5 slm.

17. The method of claim 15, wherein the acid aqueous solution has a weight percentage of less than approximately 0.5 wt % acid.

18. The method of claim 15, wherein the solution includes hydrofluoric acid.

19. The method of claim 15, wherein the solution is dispensed at approximately room temperature.
